(19) United States
(12) Patent Application Publication
(10) Pub. No.: US 2025/0383379 A1
(43) Pub. Date: Dec. 18, 2025

(54) Synchronization of data acquisition devices of an online monitoring system for monitoring an electrical distribution network

(71) Applicant: NEXANS, Courbevoie (FR)

(72) Inventors: Moussa KAFAL, Les Ulis (FR); Samuel GRIOT, LYON (FR)

(21) Appl. No.: 18/671,961

(22) Filed: May 22, 2024

(30) Foreign Application Priority Data
May 23, 2023 (FR) 2305072

(51) Int. Cl. G01R 19/25

(52) U.S. Cl. CPC G01R 19/2509; G01R 19/2513

(57) ABSTRACT

An arrangement for synchronization between at least two data acquisition devices of an online monitoring system for monitoring an electrical distribution network, each located at a known point in the network and configured to detect high-frequency events during passive data acquisition phases and to inject high-frequency signals. A first signal having at least one high-frequency pulse is injected into the network from a first data acquisition device at a first injection time t_{A1} timestamped by a first local timestamping means. After reception of the first signal by the second data acquisition device at a first reception time t_{B1} timestamped by a second local timestamping means, a second signal identical to the first signal is injected into the network from the second data acquisition device. The second signal is injected at a second injection time t_{B2} separated from the first reception time t_{B1} by a predefined duration T. On reception of the second signal at the first data acquisition device at a second reception time t_{A2} timestamped by the first local timestamping means, a synchronization difference between the first local timestamping means and the second local timestamping means is determined on the basis of the first injection time t_{A1}, of the second reception time t_{A2}, and of the predefined duration T.

### RELATED APPLICATION

The present application claims the benefit of priority from French Patent Application No. 23 05072, filed on May 23, 2023, the entirety of which is incorporated by reference.

### TECHNICAL FIELD

The present invention relates to the general field of monitoring the correct functioning of elements present in an electrical distribution network, in particular electrical cables, and more precisely the synchronization between at least two data acquisition devices belonging to an online monitoring system for monitoring an electrical distribution network.

### Technological Background

One of the main problems liable to affect the operation of an electrical transmission and/or distribution network is the occurrence of partial discharges on cables, transformers, switchgear, cable junctions, etc., which may lead to their progressive degradation and, ultimately, to destructive defects.

Detecting and locating discharges may provide crucial information to the network operator regarding the state of the insulation of distribution cables during operation and of equipment in general.

Monitoring systems based on measurements at one end of a network cable, which use time domain reflectometry (TDR) and signal processing techniques, have already been proposed. However, these systems are mainly able to be used offline and have strict limits in terms of their effectiveness and their field of application.

Other known systems, referred to as online monitoring systems, are able to detect and locate events that may represent anomalies, such as partial discharges, without affecting normal operation of the network. The information relating to the progression of the phenomenon over time may prevent the occurrence of destructive defects, thus improving the reliability indices of the network and preventing the short-circuit current from impacting other equipment. As a result, such online monitoring systems contribute to one of the important aspects of the smart grid, namely making optimum use of existing assets through implementation of optimized preventive maintenance and intelligent knowledge of the state of the assets.

As shown in FIG. 1, which partially schematically illustrates one example of a mesh electrical distribution network, the principle of online monitoring consists in placing a plurality of online data acquisition devices 1 at predefined locations in the network, for example at the ends of electrical cables present in this network. In the non-limiting example of FIG. 1, three of these online data acquisition devices 1 have been shown, placed at three known locations illustrated by points A, B and C. The two devices 1 placed at points A and B are able to detect events corresponding to a partial discharge occurring at any position of a cable or equipment of the network, for example located between points A and B or even outside these points. Similarly, the two devices 1 placed at points B and C are able to detect events corresponding to a partial discharge occurring at any position of a cable or equipment of the network, for example located between points B and C, or even outside these points.

The known principle of locating a partial discharge with this type of online monitoring system is as follows: If a partial discharge 2 occurs between points A and B of the network, two corresponding pulsed signals u_{A}(t) and u_{B}(t) will propagate in opposing directions in the network. The signal u_{A}(t) is detected by the data acquisition device 1 located at point A at a time tₒₐ_{_{A}}, and the signal u_{B}(t) is detected by the data acquisition device 1 located at point B at a time tₒₐ_{_{B}}. The location Z_{PD} of the partial discharge 2 may thus be determined using the following relationship:

$${Z}_{PD} = \frac{{t}_{c} - Δ {t}_{oa}}{2 {t}_{c}} \cdot {I}_{c} with \qquad ( 1 )$$

$$Δ {t}_{oa} = {t}_{{oa}_{A}} - {t}_{{oa}_{B}} \qquad ( 2 )$$

t_{c}, the time of flight between points A and B; and
l_{c} the known length of cable separating points A and B.

In order to be able to determine the quantity Δtₒₐ, and consequently the location Z_{PD}, it is therefore necessary to synchronize the two data acquisition devices 1 located at points A and B. In other words, the times of arrival tₒₐ_{_{A}} and tₒₐ_{_{B}} of the signals u_{A}(t) and u_{B}(t) acquired by each of the two data acquisition devices 1 must be determined in a common time frame.

As may be seen in FIG. 1, it is already known to associate each data acquisition device 1 of the monitoring system with a receiver 10 of a satellite navigation system, for example a GPS receiver 10. Each event detected by each of the data acquisition devices 1, for example the preceding signal u_{A}(t) or u_{B}(t) generated by a partial discharge, may thus be timestamped in a common reference system. This synchronization method is described for example in document WO 2021/138569. The difference between the times of arrival of the signals u_{A}(t) and u_{B}(t) at the two data acquisition devices 1, expressed in a common time frame, and consequently the location Z_{PD} of the partial discharge, may then be determined by applying relationships (1) and (2) above.

However, although the precision of the GPS may be very high, multiple factors may introduce errors, such as the effects of multiple propagation of the GPS signal, satellite localization errors, atmospheric conditions and, above all, installation difficulties. Indeed, the correct use of GPS systems involves the use of antennas that must be installed in free space to allow the satellite signal to be picked up. However, besides the fact that these antennas are expensive, many high-voltage or medium-voltage electrical distribution networks are underground distribution networks for which it is desired to minimize the need to install equipment on the surface.

Another known method, described in document WO 2004/013642 A2, consists in injecting high-frequency synchronization pulses at one of the ends of a cable with monitoring by a distribution network, using an inductive coupler. The data acquired by the monitoring systems used at both ends of the cable, generated by partial discharge pulses in the cable, thus contain both partial discharge pulses and synchronization pulses. By aligning the datasets and using the delay between the partial discharge pulse and the synchronization pulse, it is possible to obtain the location of the partial discharge. This time synchronization method uses the power cable as transmission medium for the synchronization pulses, thereby mitigating the drawback of satellite invisibility and atmospheric condition problems associated with GPS. However, the precision of this method is greatly affected by the attenuation and dispersion of the synchronization pulses propagating in the cable. This results in loss of temporal data sent via the cable.

### SUMMARY OF THE INVENTION

The aim of the present invention is to overcome the drawbacks of methods and systems for synchronizing at least two data acquisition devices of an online monitoring system for monitoring an electrical distribution network.

More precisely, one subject of the present invention is a method for synchronization between at least a first data acquisition device and a second data acquisition device of an online monitoring system for monitoring an electrical distribution network, each data acquisition device being located at a known point in the network and being configured to detect high-frequency events during passive data acquisition phases and to inject high-frequency signals, the method comprising the following steps:
injecting into the network a first signal comprising at least one high-frequency pulse from the first data acquisition device at a first injection time t_{A1} timestamped by a first local timestamping means;
receiving said first signal at the second data acquisition device at a first reception time t_{B1} timestamped by a second local timestamping means;
injecting into the network a second signal identical to said first signal from the second data acquisition device, the second signal being injected at a second injection time t_{B2} timestamped by the second local timestamping means and separated from the first reception time t_{B1} by a predefined duration T;
receiving said second signal at the first data acquisition device at a second reception time t_{A2} timestamped by the first local timestamping means; and
determining a synchronization difference Δtₒₐ between the first local timestamping means and the second local timestamping means on the basis of the first injection time t_{A1}, of the second reception time t_{A2}, and of the predefined duration T.

In one possible embodiment, said predefined duration T is greater than at least one estimated value of the time of flight of a signal between the first and second data acquisition devices.

In one possible embodiment, said first injected signal and said second injected signal comprise a sequence of high-frequency pulses of predefined period.

In one possible embodiment, said predefined duration T is greater than the sum of the estimated time-of-flight value and of said predefined period.

In one possible embodiment, the synchronization difference Δtₒₐ is determined according to the following relationship:

$$Δ {t}_{oa} = {t}_{A 2} + {TOF}^{′}$$

in which TOF′ is the time of flight of a signal between the first and second data acquisition devices, calculated according to the relationship:

$${{TOF}^{′}}^{} = \frac{1}{2} ( {t}_{A 2} - {t}_{A 1} - T )$$

In one possible embodiment, the method further comprises timestamping the high-frequency events detected by the first data acquisition device during a first passive data acquisition phase, via the first local timestamping means, and the high-frequency events detected by the second data acquisition device during a second passive data acquisition phase, via the second local timestamping means.

The first passive data acquisition phase is preferably triggered at the second reception time t_{A2} timestamped by the first local timestamping means.

The second passive data acquisition phase is preferably triggered at the second injection time t_{B2} timestamped by the second local timestamping means.

The first passive data acquisition phase and the second passive data acquisition phase may advantageously be carried out in a time window of same predetermined duration.

In one possible embodiment, the first high-frequency event detected by the first data acquisition device and the second high-frequency event detected by the second data acquisition device correspond to two signals generated by the same partial discharge at a point of the network located between the first and second data acquisition devices, and the method furthermore comprises a step of calculating the location Z_{PD} of the partial discharge using the relationship

$${Z}_{PD} = \frac{{TOF}^{′} - Δ {t}_{oa}}{2 {TOF}^{′}} \cdot {I}_{C}$$

in which l_{c} is a length of cable between the first and second data acquisition devices. In particular, particularly in the above relationship, Δtₒₐ designates the difference between the time of arrival of the partial discharge at the first data acquisition device timestamped by the first local timestamping means and the time of arrival of the partial discharge at the second data acquisition device timestamped by the second local timestamping means.

Another subject of the present invention is an online monitoring system for monitoring an electrical distribution network comprising at least a first data acquisition device and a second data acquisition device, each data acquisition device being located at a known point in the network and being configured to detect high-frequency events during passive data acquisition phases and to inject high-frequency signals, the online monitoring system being characterized in that it comprises a first local timestamping means associated with the first data acquisition device, a second local timestamping means associated with the second data acquisition device, and synchronization means configured to:
inject into the network a first signal comprising at least one high-frequency pulse from the first data acquisition device at a first injection time t_{A1} timestamped by the first local timestamping means;
receive said first signal at the second data acquisition device at a first reception time t_{B1} timestamped by the second local timestamping means;
inject into the network a second signal identical to said first signal from the second data acquisition device, the second signal being injected at a second injection time t_{B2} timestamped by the second local timestamping means and separated from the first reception time t_{B1} by a predefined duration T;
receive said second signal at the first data acquisition device at a second reception time t_{A2} timestamped by the first local timestamping means; and
determine a synchronization difference Δtₒₐ between the first local timestamping means and the second local timestamping means on the basis of the first injection time t_{A1}, of the second reception time t_{A2}, and of the predefined duration T.

In one possible embodiment, the first local timestamping means and the second local timestamping means are N-bit counters, N being an integer greater than or equal to 16.

In one possible embodiment, the first local timestamping means is integrated into the first data acquisition device, and/or the second local timestamping means is integrated into the second data acquisition device.

### BRIEF DESCRIPTION OF THE FIGURES

The following description provided with reference to the appended drawings, which are given by way of non-limiting example, will make it easy to understand what the invention consists of and how it may be implemented. In the appended figures:

FIG. 1, already described above, partially and schematically illustrates one example of an electrical distribution network with an online monitoring system comprising data acquisition devices that are synchronized in a known manner on the basis of a GPS navigation system;

FIG. 2 partially and schematically illustrates one example of an electrical distribution network with data acquisition devices that are synchronized according to one possible embodiment of the invention;

FIG. 3 schematically illustrates a data acquisition device in accordance with one possible embodiment according to the invention;

FIG. 4 illustrates possible steps for a synchronization method in accordance with the invention;

FIG. 5 schematically illustrates some steps of the method of FIG. 4.

### DESCRIPTION OF EMBODIMENT(S)

In the figures, identical or equivalent elements will bear the same reference signs. The various diagrams are not to scale.

Hereinafter, the synchronization between at least two data acquisition devices of a monitoring system according to the invention will be described in the non-limiting case where the online monitoring system is configured to identify and locate partial discharges in the network. However, the synchronization principle may be extended to any online monitoring system having multiple data acquisition devices that need to be synchronized.

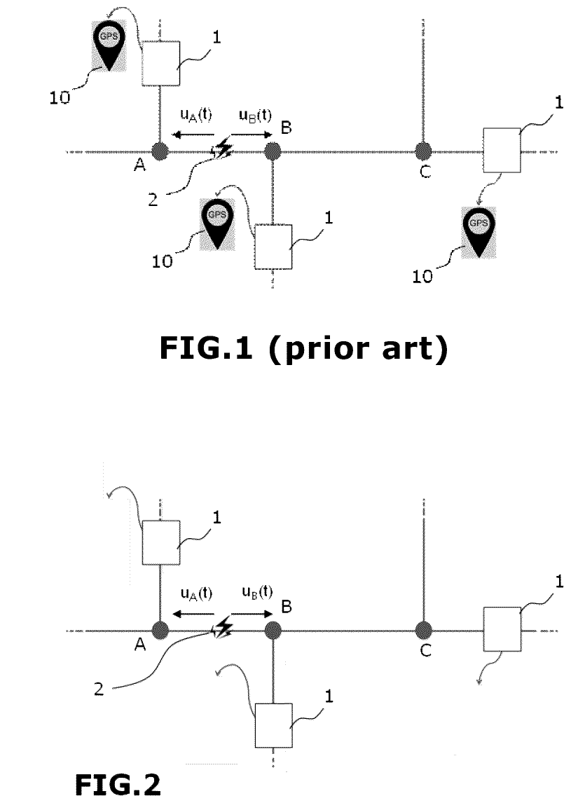

FIG. 2 partially illustrates an electrical distribution network similar to the network of FIG. 1, comprising an event monitoring system. The electrical distribution network is for example a high-voltage or medium-voltage network, composed of a plurality of electrical cables, connection accessories, equipment and/or transformers. The system comprises a plurality of acquisition devices 1 placed at various known points of the network, such as points A, B and C shown in FIG. 2. Points A, B, C where the data acquisition devices are located are preferably located at the ends of cables or of cable sections. In the non-limiting case of an underground network, the data acquisition devices 1 are preferably placed at locations that are easy to access, for example on the transformers.

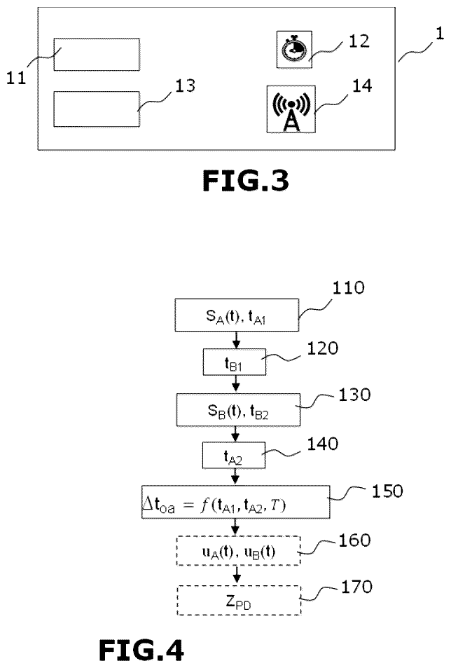

Since the devices 1 are dedicated here, without limitation, to detecting and locating partial discharges, each device 1 conventionally comprises, as illustrated schematically in FIG. 3, detection means 11 able to detect pulse events caused in the cables by the partial discharges, such as the high-frequency pulses u_{A}(t) and u_{B}(t) generated by the pulsed discharge 2 of FIG. 2. The means 11 are for example a non-invasive sensor, preferably an inductive sensor 11, located around the cable at the point where the device is located. Instead of the GPS receiver 10 in FIG. 1, the online monitoring system further comprises a local timestamping means 12 associated with each data acquisition device 1, and time synchronization means configured to implement the steps of a synchronization method according to the invention. The term “associated” is understood to mean that each local timestamping means 12 is either electrically and functionally connected to each device 1 or integrated into each device 1 as illustrated in FIG. 3. Each device 1 also comprises injection means 13 configured to generate high-frequency signals and to inject these high-frequency signals via the detection means 11. These injection means 13 form part, as will become more clearly apparent below, of the time synchronization means. Each data acquisition device 1 may also advantageously comprise a mobile communication (4G or later) or Ethernet module 14, enabling it in particular to receive control signals transmitted by a remote server (not shown) contained in the online monitoring system, or to transmit information, such as the acquired data, to this server.

Each local timestamping means 12 is preferably a precise local clock, or a 16-bit or more counter. Such a local timestamping means 12 makes it possible to timestamp each injection of a high-frequency signal, each reception of a high-frequency signal, and each event detected by the high-frequency sensor 11 at the point where the data acquisition device 1 is located, during a passive data acquisition phase.

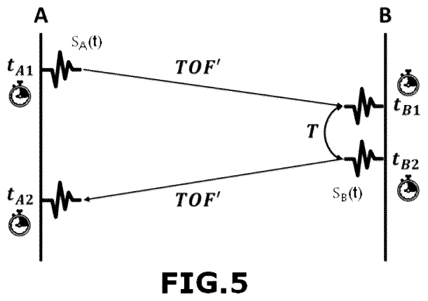

A method for time synchronization, according to the present invention, between the data acquisition devices 1 will now be described with reference to FIGS. 4 and 5. For the sake of simplification, the explanation is given with regard to the two devices 1 located at points A and B, but may easily be extended to all data acquisition devices 1 present in the online monitoring system for monitoring the electrical network. Below, the device 1 placed at point A is called the “first data acquisition device” and the device 1 placed at point B is called the “second data acquisition device”. Since the two devices are identical, they may nevertheless swap roles:

The synchronization method begins with a step 110 in which the first data acquisition device 1 generates a first signal S_{A}(t), and injects this first signal into the network, and more precisely into the cable. This first signal S_{A}(t), generated or delivered by the injection means 13 of the first device 1, comprises at least one high-frequency pulse. It is thus possible to inject this first signal into the network at point A, using the detection means 11 in an active mode (as opposed to the passive mode in which the detection means 11 receive signals). In one possible embodiment, this first signal S_{A}(t) corresponds to a sequence of high-frequency pulses of predetermined period. Use of a plurality of successive pulses, instead of a single pulse, advantageously improves the resolution of the signals and mitigates the effects of attenuation and of dispersion of the signal during its propagation through the cable. The injection time t_{A1} of this first signal is timestamped by the local timestamping means 12 integrated into, or more broadly associated with, the first device 1, and recorded locally or transmitted for recording to the central server via the communication module 14 of the first device 1.

The first injected signal propagates through the various components of the network (cables and transformers and/or switchgear, and/or cable junctions, etc.) until it reaches the second data acquisition device 1. This first signal S_{A}(t) is therefore received by the second device 1 in a step 120 via its detection means 11. The reception time t_{B1} of this first signal is timestamped by the local timestamping means 12 integrated into, or more widely associated with, the second device 1, and recorded locally.

After a predefined duration T following the reception time t_{B1}, the second data acquisition device 1 generates a second signal S_{B}(t), identical to the first signal, and injects this second signal at point B of the network, and more precisely into the cable, by using its detection means 11 in an active mode (step 130 in FIGS. 4 and 5). The injection time t_{B2} of this second signal S_{B}(t) is timestamped by the local timestamping means 12 integrated into, or more widely associated with, the second device 1, and recorded locally. The predefined duration T separating the reception time t_{B1} and injection time t_{B2} of this second signal S_{B}(t) is preferably chosen to be greater than at least one estimated value of the time of flight of a signal between the first and second data acquisition devices 1. In the case where the first signal and the second signal correspond to a sequence of high-frequency periodic pulses of predefined period T_{A/B}, the predefined duration T is preferably chosen to be greater than the sum of the estimated time-of-flight value and of said predefined period T_{A/B}. The estimated value of the time of flight through the network does not need to be accurate. It may be an average value of the time of flight through network components.

This second injected signal S_{B}(t) propagates through the various components of the network (cables and transformers and/or switchgear, and/or cable junctions, etc.) and is subjected to the same effects as those encountered during the propagation of the first signal S_{B}(t), until it reaches the first data acquisition device 1. This second signal S_{B}(t) is therefore received by the first device 1 in a step 140 via its detection means 11. The reception time t_{A2} of this second signal is timestamped by the local timestamping means 12 integrated into, or more broadly associated with, the first device 1, and recorded locally or transmitted for recording to the central server via the communication module 14 of the first device 1.

It is then possible, in a step 150, to determine a synchronization difference Δtₒₐ between the first local timestamping means 2 and the second local timestamping means 12 of the two data acquisition devices 1 on the basis of the first injection time t_{A1}, of the second reception time t_{A2}, and of the predefined duration T. More precisely, the synchronization difference Δtₒₐ is determined by calculation according to the following relationship:

$$Δ {t}_{oa} = {t}_{A 2} + {TOF}^{′}$$

in which TOF′ is the time of flight of a signal between the first and second data acquisition devices (1), calculated according to the relationship:

$${{TOF}^{′}}^{} = \frac{1}{2} ( {t}_{A 2} - {t}_{A 1} - T )$$

This calculation may be carried out locally (in the first device 1) or in a centralized manner on the remote server.

Any high-frequency event liable to be detected by the detection means 11 of the first device 1 or of the second device 1 during passive data acquisition phases will consequently be able to be timestamped first locally, via the local timestamping means 12, and then in a common reference base by virtue of the knowledge of the synchronization difference Δtₒₐ between the two data acquisition devices 1.

In the non-limiting case where the data acquisition devices 1 are dedicated to detection of high-frequency events corresponding to signals u_{A}(t) and u_{B}(t) generated by the same partial discharge 2, the method therefore comprises triggering a first passive phase and a second passive phase of detection of these events in the first data acquisition device 1 and second data acquisition device 1, respectively, during a time window of the same predetermined duration for both phases (step 160).

In one possible embodiment, the first passive data acquisition phase is triggered at the second reception time t_{A2} and the second passive data acquisition phase is triggered at the second injection time t_{B2}. On detection of the signals u_{A}(t) and u_{B}(t), it is then possible to calculate the location Z_{PD} of the partial discharge according to the relationship

$${Z}_{PD} = \frac{{TOF}^{′} - Δ {t}_{oa}}{2 {TOF}^{′}} \cdot {I}_{C}$$

in which l_{c} is a length of cable between the first and second data acquisition devices 1. This calculation step 170 may for example be carried out on the remote central server. In particular, particularly in the above relationship, Δtₒₐ designates the difference between the time of arrival of the partial discharge 2 at the first data acquisition device 1 timestamped by the first local timestamping means 12 and the time of arrival of the partial discharge 2 at the second data acquisition device 1 timestamped by the second local timestamping means 12.

Steps 110 to 150 are preferably repeated periodically (for example one or more times a day) so as to compensate for drifts that may affect the network, such as temperature changes, overloads, and/or dispersion in the counters 12.

1. A method for synchronization between at least a first data acquisition device and a second data acquisition device of an online monitoring system for monitoring an electrical distribution network, each data acquisition device being located at a known point in the network and being configured to detect high-frequency events during passive data acquisition phases and to inject high-frequency signals, the method comprising the steps of:
injecting into the network a first signal comprising at least one high-frequency pulse from the first data acquisition device at a first injection time t_{A1} timestamped by a first local timestamping means;
receiving said first signal at the second data acquisition device at a first reception time t_{B1} timestamped by a second local timestamping means;
injecting into the network a second signal identical to said first signal from the second data acquisition device, the second signal being injected at a second injection time t_{B2} timestamped by the second local timestamping means and separated from the first reception time t_{B1} by a predefined duration T;
receiving said second signal at the first data acquisition device at a second reception time t_{A2} timestamped by the first local timestamping means; and
determining a synchronization difference Δtₒₐ between the first local timestamping means and the second local timestamping means on the basis of the first injection time t_{A1}, of the second reception time t_{A2}, and of the predefined duration T.

2. The method according to claim 1, wherein said predefined duration T is greater than at least one estimated value of the time of flight of a signal between the first and second data acquisition devices.

3. The method according to claim 1, wherein said first injected signal and said second injected signal comprise a sequence of high-frequency pulses of predefined period.

4. The method according to claim 2, wherein said predefined duration T is greater than the sum of the estimated time-of-flight value and of said predefined period.

5. The method according to claim 1, wherein the synchronization difference Δtₒₐ is determined according to the following relationship:
$$Δ {t}_{o a} = {t}_{A 2} + {TOF}^{′}$$
in which TOF′ is the time of flight of a signal between the first and second data acquisition devices (1), calculated according to the relationship:
$${{TOF}^{′}}^{} = \frac{1}{2} ( {t}_{A 2} - {t}_{A 1} - T )$$

6. The method according to claim 1, further comprising timestamping the high-frequency events detected by the first data acquisition device during a first passive data acquisition phase, via the first local timestamping means, and the high-frequency events detected by the second data acquisition device during a second passive data acquisition phase, via the second local timestamping means.

7. The method according to claim 6, wherein the first passive data acquisition phase is triggered at the second reception time t_{A2} timestamped by the first local timestamping means.

8. The method according to claim 6, wherein the second passive data acquisition phase is triggered at the second injection time t_{B2} timestamped by the second local timestamping means.

9. The method according to claim 6, wherein the first passive data acquisition phase and the second passive data acquisition phase are carried out in a time window of same predetermined duration.

10. The method according to claim 6, wherein the first high-frequency event detected by the first data acquisition device and the second high-frequency event detected by the second data acquisition device correspond to two signals generated by the same partial discharge at a point of the network located between the first and second data acquisition devices, and in that the method furthermore comprises a step of calculating the location Z_{PD} of the partial discharge using the relationship
$${Z}_{PD} = \frac{{TOF}^{′} - Δ {t}_{oa}}{2 {TOF}^{′}} \cdot {I}_{C}$$
in which l_{c} is a length of cable between the first and second data acquisition devices, and
in which TOF′ is the time of flight of a signal between the first and second data acquisition devices (1), calculated according to the relationship:
$${{TOF}^{′}}^{} = \frac{1}{2} ( {t}_{A 2} - {t}_{A 1} - T ) .$$

11. An online monitoring system for monitoring an electrical distribution network having at least a first data acquisition device and a second data acquisition device, each data acquisition device being located at a known point in the network and being configured to detect high-frequency events during passive data acquisition phases and to inject high-frequency signals, the online monitoring system comprising:
a first local timestamping means associated with the first data acquisition device, a second local timestamping means associated with the second data acquisition device, and synchronization means configured to:
inject into the network a first signal comprising at least one high-frequency pulse from the first data acquisition device at a first injection time t_{A1} timestamped by the first local timestamping means;
receive said first signal at the second data acquisition device at a first reception time t_{B1} timestamped by the second local timestamping means;
inject into the network a second signal identical to said first signal from the second data acquisition device, the second signal being injected at a second injection time t_{B2} timestamped by the second local timestamping means and separated from the first reception time t_{B1} by a predefined duration T;
receive said second signal at the first data acquisition device at a second reception time t_{A2} timestamped by the first local timestamping means; and
determine a synchronization difference Δtₒₐ between the first local timestamping means and the second local timestamping means on the basis of the first injection time t_{A1}, of the second reception time t_{A2}, and of the predefined duration T.

12. The on-line monitoring system according to claim 11, wherein the first local timestamping means and the second local timestamping means are N-bit counters, N being an integer greater than or equal to 16.

13. The on-line monitoring system according to claim 11, wherein the first local timestamping means is integrated into the first data acquisition device (1), and/or the second local timestamping means is integrated into the second data acquisition device.
